(19) United States
(12) Patent Application Publication
(10) Pub. No.: US 2024/0372529 A1
(43) Pub. Date: Nov. 7, 2024

(54) LADDER FILTER WITH EXTRACTED POLES FOR IMPROVED BAND EDGE STEEPNESS

(71) Applicant: Murata Manufacturing Co., Ltd., Nagaokakyo-shi (JP)

(72) Inventors: Bryant GARCIA, Mississauga, CA (US); Greg HEY-SHIPTON, Santa Barbara, CA (US)

(21) Appl. No.: 18/645,485

(22) Filed: Apr. 25, 2024

Related U.S. Application Data
(60) Provisional application No. 63/499,511, filed on May 2, 2023.

(51) Int. Cl. H03H 9/17; H03H 9/13; H03H 9/56

(52) U.S. Cl. CPC H03H 9/173; H03H 9/133; H03H 9/175; H03H 9/568

(57) ABSTRACT

A bandpass filter is provided that includes a plurality of bulk acoustic resonators. Each resonator includes a piezoelectric layer, an interdigital transducer (IDT) on the piezoelectric layer, and a dielectric layer disposed on and between interleaved fingers of the IDT. Moreover, the plurality of bulks acoustic resonators includes series resonators connected in series between an input and an output of the bandpass filter, shunt resonators connected between a ground and a node between a respective pair of the plurality of series resonators, a first extracted pole resonator connected between the ground and a node between the input and a first series resonator, and a second extracted pole resonator connected between the ground and a node between the output and a last series resonator. One of the extracted pole resonators has a resonance frequency that is higher than an upper edge of a passband of the bandpass filter.

### CROSS REFERENCE TO RELATED APPLICATIONS

This application claims priority to U.S. Provisional Patent Application No. 63/499,511, filed May 2, 2023, the contents of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band may depend on the specific application. For example, in some cases a “pass-band” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

Thus, according to an exemplary aspect, a bandpass filter is provided that includes a plurality of bulk acoustic resonators that each comprise a piezoelectric layer, an interdigital transducer (IDT) on the piezoelectric layer and having a plurality of interleaved fingers, and a dielectric layer disposed on and between the interleaved fingers of the IDT. Moreover, the plurality of bulk acoustic resonators includes a plurality of series resonators connected in series between an input and an output of the bandpass filter, a plurality of shunt resonators that are each connected between a ground and a node between a respective pair of the plurality of series resonators, a first extracted pole resonator connected between the ground and a node between the input and a first series resonator from among the plurality of series resonators, and a second extracted pole resonator connected between the ground and a node between the output and a last series resonator from among the plurality of series resonators. In this aspect, one of the first and second extracted pole resonators has a resonance frequency that is higher than an upper edge of a passband of the bandpass filter. Yet further the other of the first and second extracted pole resonators has a resonance frequency that is lower than a lower edge of the passband of the bandpass filter.

In another exemplary aspect, each of the plurality of bulk acoustic resonators comprises a substrate and an intermediate dielectric layer that couples the substrate to the piezoelectric layer, and wherein the piezoelectric layer includes a diaphragm over a cavity in the intermediate dielectric layer with the interleaved fingers of the respective IDT on the diaphragm.

In another exemplary aspect, a thickness of the respective dielectric layers of each of the first and second extracted pole resonators is different than a thickness of the respective dielectric layers of the plurality of series resonators and the plurality of shunt resonators. In a refinement of this aspect, the thickness of the respective dielectric layers of the plurality of series resonators is thicker than the thickness of respective dielectric layer of the one of the first and second extracted pole resonators that has the resonance frequency that is higher than the upper edge of the passband of the bandpass filter. Moreover, the thickness of the respective dielectric layers of the plurality of shunt resonators is thinner than the thickness of respective dielectric layer of the other of the first and second extracted pole resonators that has a resonance frequency that is lower than a lower edge of the passband of the bandpass filter. In this aspect, the respective thicknesses of the dielectric layers of the plurality of bulk acoustic resonators are measured in a direction orthogonal to surfaces of the respective piezoelectric layers.

In another exemplary aspect, a thickness of the respective piezoelectric layers of each of the first and second extracted pole resonators is different than a thickness of the respective piezoelectric layers of the plurality of series resonators and the plurality of shunt resonators.

In another exemplary aspect, a stack thickness of each of the first and second extracted pole resonators is different than a stack thickness of the plurality of series resonators and the plurality of shunt resonators. In a refinement of this aspect, the stack thickness of the plurality of series resonators is thicker than the stack thickness of the one of the first and second extracted pole resonators that has the resonance frequency that is higher than the upper edge of the passband of the bandpass filter. Moreover, the stack thickness of the plurality of shunt resonators is thinner than the stack thickness of the other of the first and second extracted pole resonators that has a resonance frequency that is lower than a lower edge of the passband of the bandpass filter. In this aspect, the respective stack thicknesses of the plurality of bulk acoustic resonators are measured in a direction orthogonal to surfaces of the respective piezoelectric layers.

In another exemplary aspect, a pitch of the respective IDTs of each of the first and second extracted pole resonators is different than a pitch of the respective IDTs of the plurality of series resonators and the plurality of shunt resonators. In this aspect, the pitch of the respective IDTs of the plurality of series resonators is larger than a pitch of the one extracted pole resonator that has the resonance frequency that is higher than the upper edge of the passband of the bandpass filter. Moreover, the pitch of the respective IDTs of the plurality of shunt resonators is less than a pitch of the other of the first and second extracted pole resonators has a resonance frequency that is lower than a lower edge of the passband of the bandpass filter.

In another exemplary aspect, the respective IDTs of each of the plurality of bulk acoustic resonators are configured to excite primary shear acoustic waves in the respective piezoelectric layer in response to a radio frequency signal or a microwave signal applied to the IDT.

In another exemplary aspect, each of the plurality of bulk acoustic resonators comprises a substrate and a Bragg reflector that couples the substrate to the piezoelectric layer.

According to yet another exemplary aspect, a bandpass filter is provided that includes a plurality of bulk acoustic resonators that each include a piezoelectric layer, an interdigital transducer (IDT) on the piezoelectric layer and having a plurality of interleaved fingers, and a dielectric layer disposed on and between the interleaved fingers of the IDT. In this aspect, the plurality of bulks acoustic resonators includes a plurality of series resonators connected in series between an input and an output, a plurality of shunt resonators that are each connected between a ground and a node that is between a respective pair of series resonators of the plurality of series acoustic resonators, a high side extracted pole resonator connected between the ground and either the input or the output, and a low side extracted pole resonator connected between the ground and the other of the input or the output. Moreover, the high side extracted pole resonator has a resonance frequency that is higher than an upper edge of a passband of the bandpass filter and the low side extracted pole resonator has a resonance frequency that is lower than a lower edge of a passband of the bandpass filter.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a schematic block diagram of a filter device with extracted poles according to an exemplary aspect.

FIG. 7 is a plot of the admittance of a theoretical lossless acoustic resonator.

FIG. 8 is a graph of the S(2,1) parameter of a bandpass filter determined by simulation using models for each of the resonators according to an exemplary aspect.

FIG. 9 illustrates a graph demonstrating a response of extracted pole resonator on the S(2,1) parameter of the bandpass filter shown in FIG. 8.

FIG. 10 illustrates a flowchart of a method of manufacturing a filter as described herein according to an exemplary aspect.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

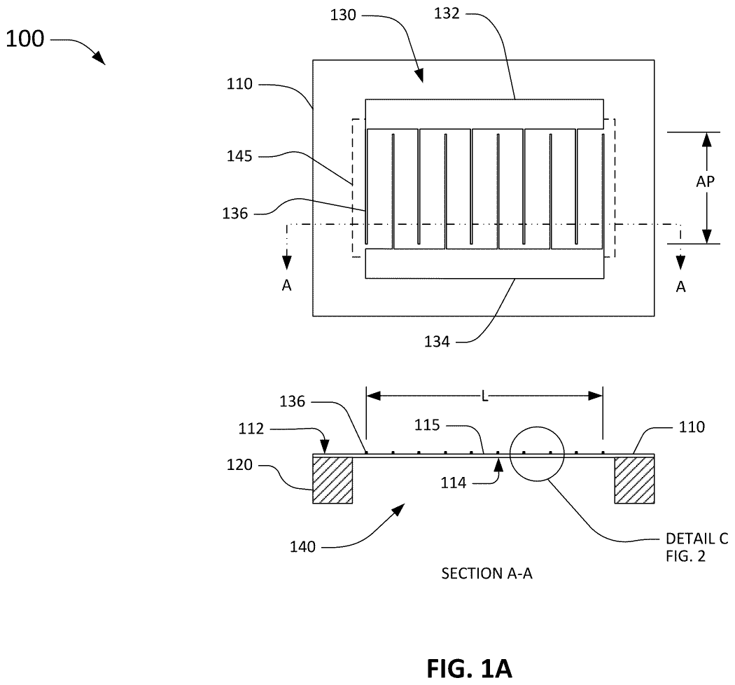

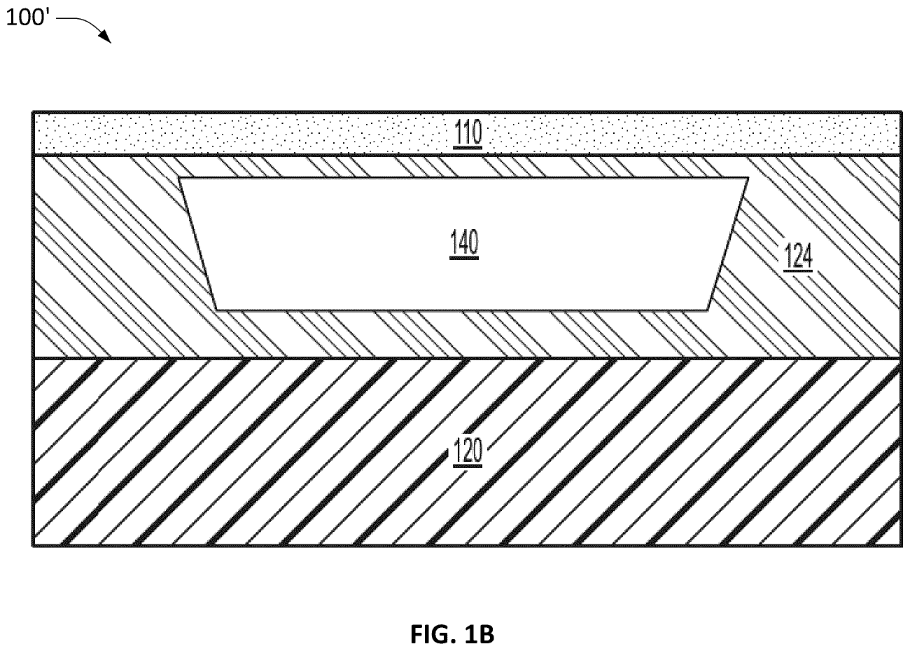

FIG. 1A shows a simplified schematic top view and orthogonal cross-sectional views of a bulk acoustic resonator device, namely a transversely excited film bulk acoustic resonator (XBAR) 100. XBAR resonators, such as the resonator 100, may be used in a variety of RF filters including band-rejection filters, band-pass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art. Moreover, the term “substantially” as used herein is used to describe when components, parameters and the like, are predominant in view of other comparable features or even in comparison to the absence of the same feature, or are generally the same (i.e., “substantially constant”), but it takes into account minor variations resulting from manufacturing variances, for example. For example, the “unit pitch” as described below between respective finger units of the IDT is described as being “substantially constant” across the length of the IDT. For purposes of this disclosure, this means that the unit pitch of the IDT is designed to be constant based on the configured manufacturing and metal patterning processes used to form the IDT fingers of the exemplary aspects, but may vary slightly (e.g., within an acceptable threshold or percentage) in practice due to possible manufacturing variances as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90, 0) and (0, 128-90, 0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

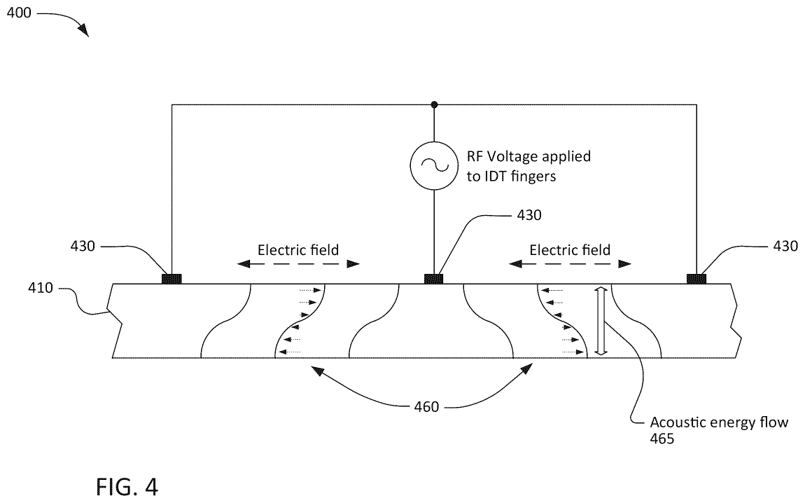

The first and second busbars 132, 134 are configured as the terminals of the XBAR 100. In operation, a radio frequency signal or microwave signal applied between the two busbars 132, 134 of the IDT 130 primarily excites an acoustic mode (i.e., a primarily shear acoustic mode and/or primary shear acoustic wave(s)) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

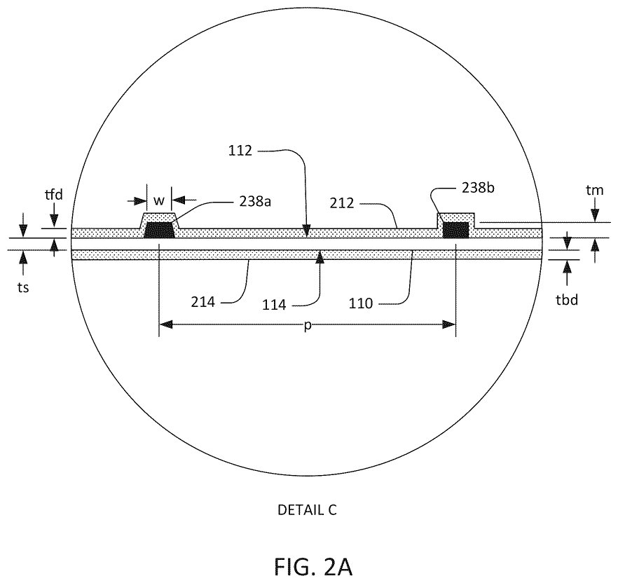

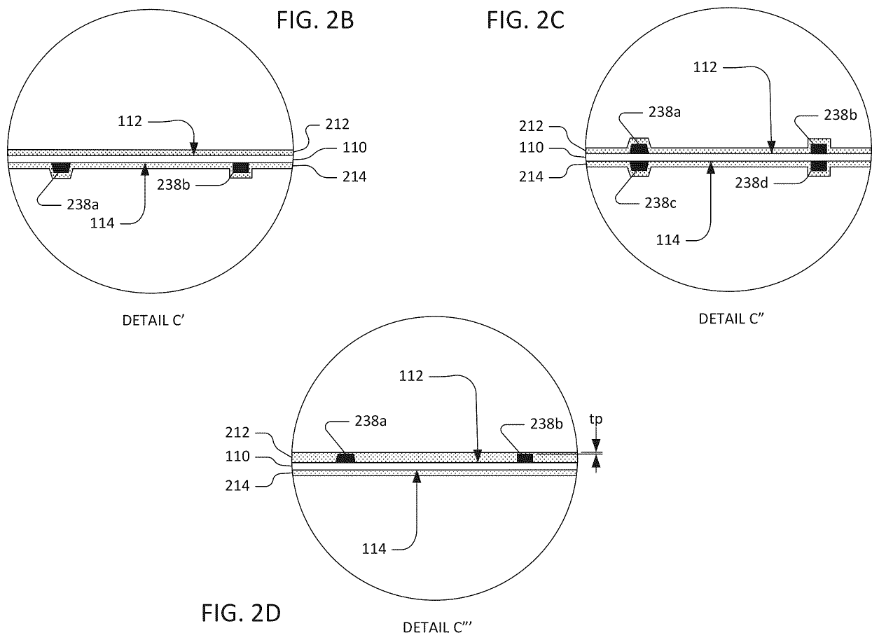

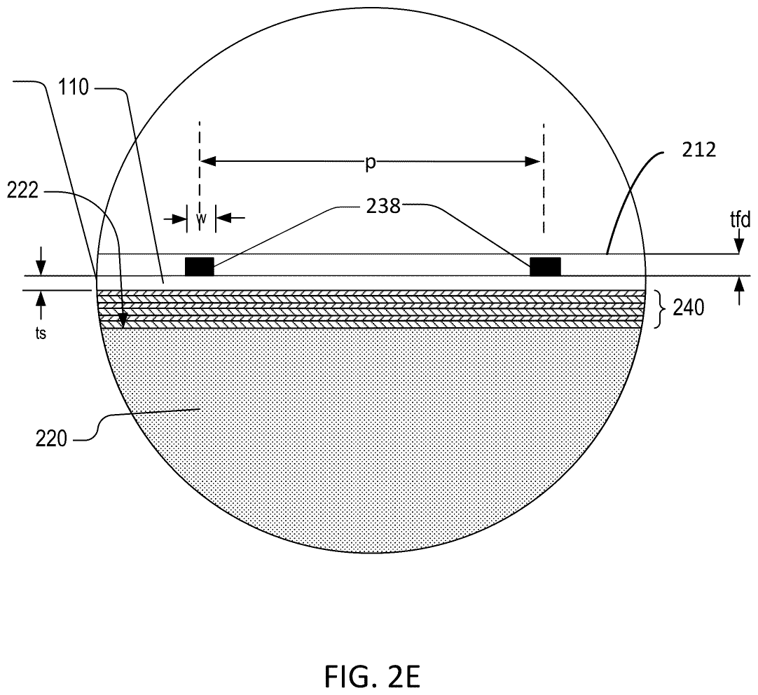

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects.

Dimension p is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

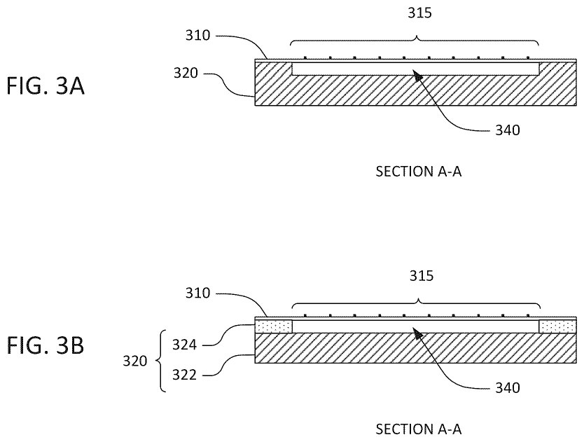

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

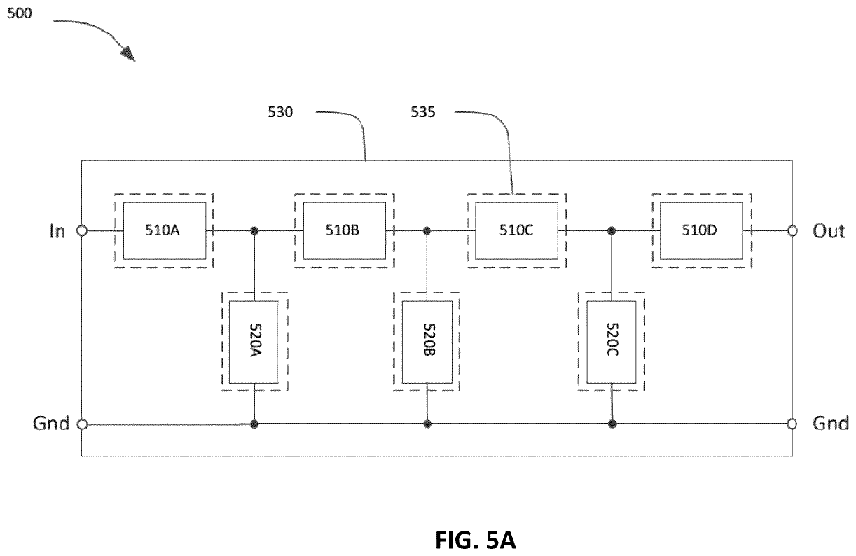

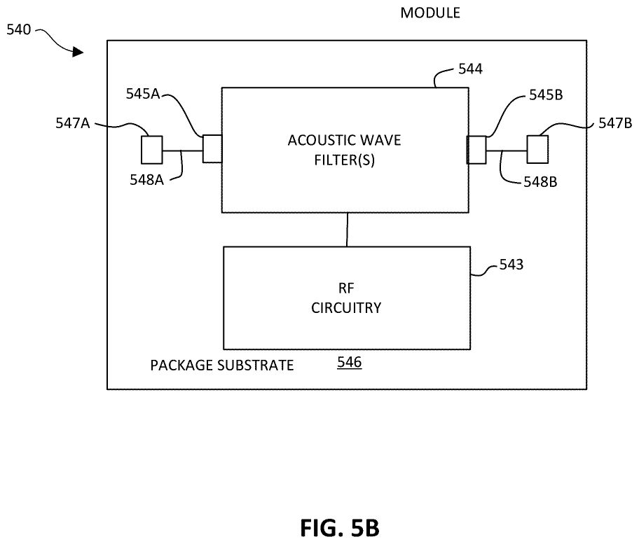

FIG. 5A is a schematic circuit diagram and layout for a high frequency band-pass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, and 510C and the shunt resonators 520A and 520B can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

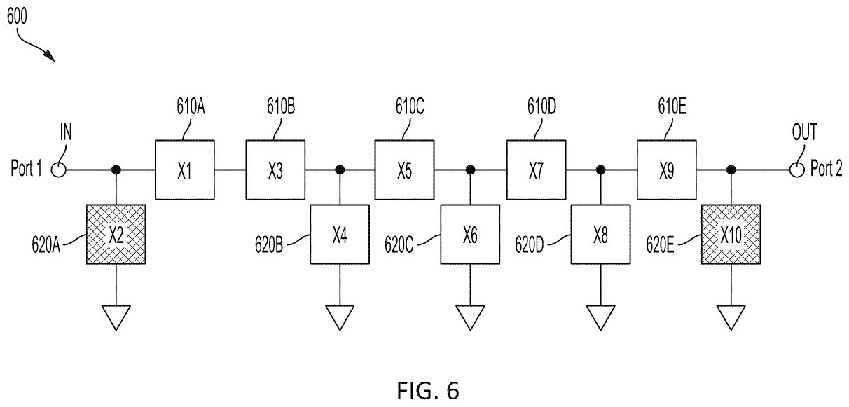

FIG. 6 is a schematic block diagram of a filter device with extracted poles according to an exemplary aspect. In general, the pass-band filter 600 illustrated in FIG. 6 is a refinement of the high frequency band-pass filter 500 described above. That is, band-pass filter 600 is configured using the XBAR resonator configurations, such as the XBAR 100 discussed above in reference to FIG. 1A and/or the XBAR 100′ discussed above in reference to FIG. 1B.

As shown, the filter 600 has a ladder filter architecture including five series resonators 610A, 610B, 610C, 610D and 610E (also labeled X1, X3, X5, X7 and X9) and also five shunt resonators 620A, 620B, 620C, 620D and 620E (also labeled X2, X4, X6, X8 and X10). As shown, the five series resonators 610A to 610E are connected in series between a first port IN and a second port OUT. That is, the first and second ports are labeled “In” and “Out”, respectively. It is noted that the filter 600 can be bidirectional and either port and serve as the input or output of the filter. According to the exemplary aspect, series resonator 610A can be a first series resonator of the plurality of series acoustic resonators and series resonator 610E can be a last (or nth) series resonator of the plurality of series acoustic resonators. In general, filter 600 can have two to n series resonators where the series resonator connected the first port IN is a first series resonator and the series resonator connected the second port OUT is a last (or nth) series resonator.

The five shunt resonators 620A to 620E are connected from respective nodes between the series resonators to ground (e.g., a ground connection), from a node between the input and a first series resonator 610A to ground, and/or from a node between the last series (or nth) resonator 610E and the output to ground. That is, the plurality of shunt acoustic resonators 620A to 620E are each connected between a ground and one of the input, the output, and a node between a pair of series resonators of the plurality of series acoustic resonators. In an exemplary aspect, all the shunt resonators (also labeled as X2, X4, X6, X8 and X10) and series resonators (also labeled as X1, X3, X5, X7 and X9) are XBARs that can be implemented on a single die. However, in an alternative aspect, one or more of the XBARs can be implemented on a separate die as would be appreciated to one skilled in the art and as described above according to the exemplary aspect of FIG. 5A.

In an exemplary aspect, the five series resonators 610A to 610E and the five shunt resonators 620A to 620E the filter 500 are formed on one or more layers of piezoelectric material bonded either directly or via one or more intermediate (e.g., dielectric) layers to a substrate (not visible). That is, the series and shunt resonators can have one or more bonding layers formed on a layer of piezoelectric material. Moreover, the series and shunt resonators can have one or more layers of piezoelectric material bonded to the bonding layer. During manufacture, the single layer may be divided into a plurality of piezoelectric layers, i.e., one piezoelectric layer or diaphragm for each acoustic resonator.

According to an exemplary aspect, each of the series resonators 610A to 610E and the shunt resonators 620A to 620E can have an XBAR configuration as described above with respect to FIGS. 1-3 in which a diaphragm with IDT fingers is disposed over a cavity. However, in an alternative aspect, the series resonators 610A to 610E and the shunt resonators 620A to 620E can be solidly mounted in which the diaphragm with IDT fingers is mounted on or above a Bragg mirror, which is in turn can be mounted on a substrate. In such a configuration, the piezoelectric diaphragm is supported by the substrate with a Bragg mirror disposed therebetween. For example, the conductor pattern with IDT fingers can be on a top surface of the piezoelectric layer 110, such as the front surface 112 discussed above, opposite the Bragg mirror. An example of such a configuration is shown FIG. 2E and described above. Thus, each of the plurality of resonators of passband filter 600 can have a solidly mounted XBAR configuration in an alternative aspect.

Moreover, each resonator includes a respective IDT (not shown), such as the IDT 130 of FIG. 1A, with at least the fingers of the IDT disposed over a cavity, such as the cavity 140 in the substrate 120 of FIG. 1A and/or in the dielectric layer 124 of FIG. 1B, and at or on at least one surface of a piezoelectric material, such as the piezoelectric layer 110 of FIGS. 1A and 1B. In this and similar contexts, the term “respective” means “relating things each to each,” which is to say with at least a one-to-one correspondence. In an exemplary aspect, each IDT can be disposed over a respective cavity, but in other filters, the IDTs of two or more resonators may be disposed over a single cavity. Moreover, according to an exemplary aspect as described as follows, one or more of the series and shunt resonators of the filter 600 can have passivation layer configurations on the IDT structure.

According to an exemplary aspect, the band-pass filter 600 is configured using an extracted pole technique that improves the performance of the acoustic filter. In particular, the band-pass filter 600 is configured with a pair of “extracted pole” resonators. For purposes of this disclosure, “extracted pole” resonators are acoustic resonators with resonances (i.e., resonant frequencies) outside the filter passband to enhance rejection and band edge steepness of the passband. As will be discussed in detail below, the extracted pole resonators can be shunt resonators with a frequency tuning variation configuration, such that their respective resonances frequencies are outside the filter passband. According to this configuration, the terms of the band edge steepness are increased (i.e., sharper slope) through configuration of the extracted pole resonators. Moreover, the extracted pole resonators can provide improved one-sided rejection to create a deeper stopband than a standard ladder filter. A frequency tuning variation may include one or more of a stack height (or thickness variation) such as a variation of dielectric thickness, piezoelectric thickness, different dies/substrates, or any combination thereof. Another example of a frequency tuning variation may include a pitch that is different than a pitch of the plurality of series acoustic resonators and the plurality of shunt acoustic resonators other than the first and second extracted pole resonators. In some embodiments, any combination of these frequency tuning variations may be used to enable one or more of the extracted pole resonators to have respective resonant frequencies outside the filter passband.

Thus, according to the exemplary aspect shown in FIG. 6, a bandpass filter 600 is provided that includes a plurality of bulk acoustic resonators that each include a piezoelectric layer, an IDT on the piezoelectric layer and having a plurality of interleaved fingers, and a dielectric layer disposed on and between the interleaved fingers of the IDT. As shown, the plurality of bulks acoustic resonators includes a plurality of series resonators 610A-610E connected in series between an input (e.g., Port 1) and an output (e.g., Port 2) of the bandpass filter 600, and also, a plurality of shunt resonators 620A-620E that are each connected between a ground and a node between a respective pair of the plurality of series resonators. The shunt resonators can include a first extracted pole resonator (e.g., resonator 620A, e.g. “X2”) connected between the ground and a node between the input and a first series resonator (e.g., resonator 610A) from among the plurality of series resonators, and a second extracted pole resonator (e.g., resonator 620E, e.g. “X10”) connected between the ground and a node between the output and a last series resonator (e.g., resonator 610E from among the plurality of series resonators. Moreover, one of the first and second extracted pole resonators 620A and 620E has a resonance frequency that is higher than an upper edge of a passband of the bandpass filter. Moreover, the other of the first and second extracted pole resonators 620A and 620E has a resonance frequency that is lower than a lower edge of the passband of the bandpass filter.

In a conventional configuration, all shunt resonators (e.g., shunt resonators X2, X4, X6, X8 and X10) have a resonant frequency that is lower than the lower edge fL of the passband of the acoustic filter. In addition, the antiresonance fa is approximately the average of the frequency of the lower edge fL and upper edge fU of the passband (i.e., fL+fU/2).

However, according to an exemplary aspect, the plurality of shunt acoustic resonators 620A to 620E include a first extracted pole resonator 620A connected between the ground and a node between the input and a first series acoustic resonator, such as resonator 610A, and a second extracted pole resonator 620E connected between the ground and a node between the output and a last of the series acoustic resonators, such as resonator 610E. One of the extracted pole resonators (either of 620A or 620E) can be disposed on the “high side” (e.g., a “high side extracted pole resonator”), while the other of the extracted pole resonators (the other 620A or 620E) can be disposed on the “low side” (e.g., a “low side extracted pole resonator”). That is, extracted pole resonator 620A can be a low side extracted pole resonator and extracted pole resonator 620E can be a high side extracted pole resonator, or vice versa. In addition, while filter 600 is illustrated with a pair of extracted pole resonators 620A and 620E, in an alternative aspect, a filter 600 can be provided with only one of extracted pole resonators 620A and 620E.

In the exemplary aspect, the one of the first and second extracted pole resonators that is configured as the high side extracted pole resonator will have a frequency tuning variation configuration such that its resonance frequency is higher than an upper edge of a passband of the bandpass filter and have an anti-resonance frequency that is lower than respective anti-resonance frequencies of all of the plurality of series acoustic resonators. The other of the first and second extracted pole resonators that is configured as the low side extracted pole resonator will have a frequency tuning variation configuration such that its resonance frequency is lower than a lower edge of a passband of the bandpass filter and an anti-resonance frequency that is higher than respective anti-resonance frequencies the remaining shunt resonators (i.e., shunt resonators 620B, 620C and 620E). Thus, according to this configuration, the “poles” of the band-pass filter 600 (i.e., the outer edge resonators of the filter) are each XBARs that have a resonant frequency that is greater than a frequency of the upper edge fU of the passband and that is less greater than a frequency of the lower edge fL of the passband.

As shown in FIG. 6 and described above, the selected resonators according to the pole technique of the exemplary aspect (also referred to as the “extracted pole resonators”) are the outermost resonators highlighted in grey, i.e., shunt resonator 620A (X2) and shunt resonator 620E (X10). That is, shunt resonator 620A (as the first extracted pole resonator) is connected between a ground connection and a first node disposed between the first port (e.g., “IN” port) and the first series resonator 610A. Moreover, shunt resonator 620E (as the second extracted pole resonator) is connected between a ground connection and an nth node disposed between the second port (e.g., “out” port) and the nth series resonator (i.e., series resonator 620A). It is noted that while five series resonators 610A to 610E are shown, the filter 600 can have n series resonators with the two “pole” resonators being the two outermost shunt resonators as shown in the configuration.

According to the exemplary aspect, the motional resonance of each of the shunt resonators 620B, 620C and 620D creates a transmission zero at a respective frequency lower than the passband of the bandpass filter 600. The motional resonance of the respective extracted pole resonators 620A and 620E creates a transmission zero at respective frequencies at the edges or outside the edges of the passband of the bandpass filter 600. Moreover, the relocation of extracted pole resonator 620A from the junction of X1 and X3 is done in order to improve the physical realizability of resonator extracted pole resonator 620A. In alternative aspects, any of the shunt resonators could have been extracted, or added, at any of the nodes between series resonators according to various exemplary aspects.

As described above, the extracted pole resonators are shunt resonators with a frequency tuning variation configuration such that the “poles” of the band-pass filter 600 have a resonant frequency that is greater than a frequency of the upper edge fU of the passband and/or that is less than a frequency of the lower edge fL of the passband. In one exemplary aspect, the frequency tuning variation configuration is a variation of the dielectric layers of the extracted pole resonators. In particular, the filter 600 can have a configuration in which a thickness of the respective dielectric layers of each of the first and second extracted pole resonators is different than a thickness of the respective dielectric layers of the plurality of series resonators 610A to 610E and the plurality of shunt resonators 620B to 620D (other than the extracted pole resonators 620A and 620E.

In this configuration, the thickness of the respective dielectric layers of the plurality of series resonators 610A to 610E is thicker than the thickness of respective dielectric layer of the one of the first and second extracted pole resonators that has the resonance frequency that is higher than the upper edge of the passband of the bandpass filter, i.e., the “high side extracted pole resonator” such as resonator 610E. Moreover, the thickness of the respective dielectric layers of the plurality of shunt resonators 620B to 620D is thinner than the thickness of respective dielectric layer of the other of the first and second extracted pole resonators that has a resonance frequency that is lower than a lower edge of the passband of the bandpass filter, i.e., the “low side extracted pole resonator” such as resonator 610A. It should be appreciated that the respective thicknesses of the dielectric layers of the plurality of bulk acoustic resonators are measured in a direction orthogonal to surfaces of the respective piezoelectric layers.

In another exemplary aspect, the frequency tuning variation configuration can be based on the overall stack thickness of each acoustic resonator, where the stack can be considered all of the layers that make up the resonator in the vertical or thickness direction. For example, the stack of acoustic resonator 100′ shown in FIG. 1B includes substrate 120, dielectric layer 124 and piezoelectric layer 110. It could also include a dielectric layer on top of the piezoelectric layer 110, which is not shown in FIG. 1B, but is described above. In this aspect, the stack thickness of each of the first and second extracted pole resonators (e.g., resonators 620A and 620E) is different than a stack thickness of the plurality of series resonators 610A to 610E and the plurality of shunt resonators 620B to 620D, other than the extracted pole resonators. This configuration can be achieved, for example, where a thickness of the respective piezoelectric layers of each of the first and second extracted pole resonators (e.g., resonators 620A and 620E) is different than a thickness of the respective piezoelectric layers of the plurality of series resonators 610A to 610E and the plurality of shunt resonators 620B to 620D, other than the extracted pole resonators.

In any event, in this configuration, the stack thickness of the plurality of series resonators is thicker than the stack thickness of the one of the first and second extracted pole resonators that has the resonance frequency that is higher than the upper edge of the passband of the bandpass filter, i.e., the “high side extracted pole resonator” such as resonator 610E. Moreover, the stack thickness of the plurality of shunt resonators is thinner than the stack thickness of the other of the first and second extracted pole resonators that has a resonance frequency that is lower than a lower edge of the passband of the bandpass filter, i.e., the “low side extracted pole resonator” such as resonator 610A. Again, the respective stack thicknesses of the plurality of bulk acoustic resonators are measured in a direction orthogonal to surfaces of the respective piezoelectric layers.

In another exemplary aspect, the frequency tuning variation configuration can be based on the respective pitches of the plurality of bulk acoustic resonators. In this aspect, a pitch of the respective IDTs of each of the first and second extracted pole resonators (e.g., resonators 620A and 620E) is different than a pitch of the respective IDTs of the plurality of series resonators 610A to 610E and the plurality of shunt resonators 620B to 610D, other than the extracted pole resonators. More particular, the pitch of the respective IDTs of the plurality of series resonators 610A to 610E is larger than a pitch of the one extracted pole resonator that has the resonance frequency that is higher than the upper edge of the passband of the bandpass filter, i.e., the “high side extracted pole resonator” such as resonator 610E. Moreover, the pitch of the respective IDTs of the plurality of shunt resonators is less than a pitch of the other of the first and second extracted pole resonators has a resonance frequency that is lower than a lower edge of the passband of the bandpass filter, i.e., the “low side extracted pole resonator” such as resonator 610A.

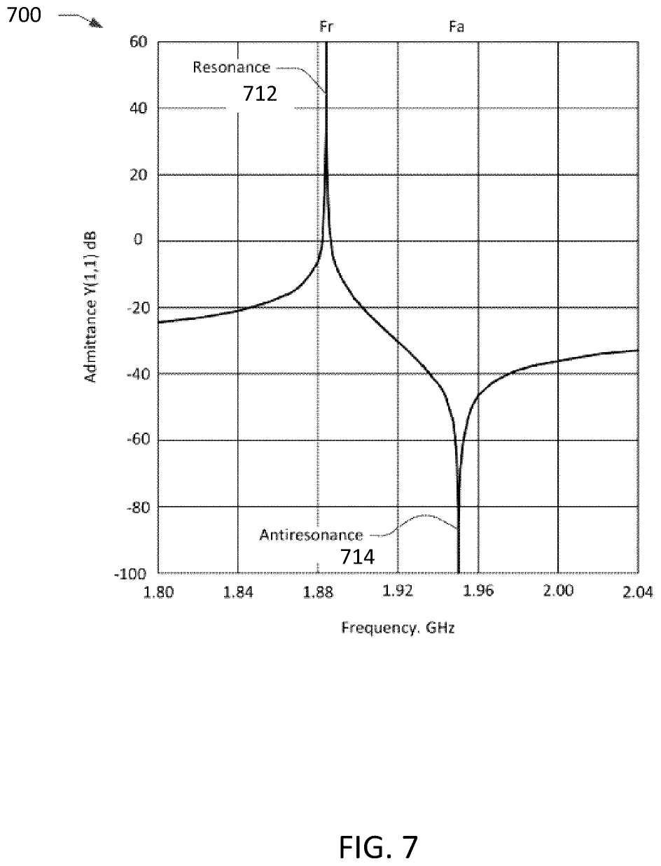

FIG. 7 is a plot 700 of the admittance of a theoretical lossless acoustic resonator, which is obtained using a finite element method (FEM) simulation. As shown, the admittance exhibits a motional resonance 712 where the admittance of the resonator approaches infinity, and an anti-resonance 714 where the admittance of the resonator approaches zero. In general, the theoretical lossless acoustic resonator can be considered a short circuit at the frequency of the motional resonance 712 and an open circuit at the frequency of the anti-resonance 714. The frequencies of the motional resonance 712 and the anti-resonance 714 are representative, and a resonator may be designed for other frequencies.

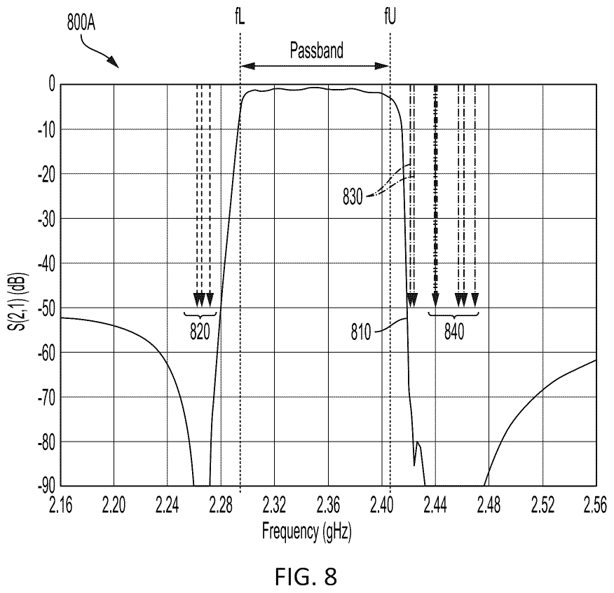

FIG. 8 is a graph 800A of the S(2,1) parameter of the bandpass filter 600 determined by FEM simulation using models for each of the resonators. In general, the passband is defined by a lower edge fL and an upper edge fU. It should also be understood that a passband can be considered a frequency band where the insertion loss of filter 600 is less than 1 dB or 3 dB, or the frequency band where the return loss at the input to the filter is at least 10 dB. Other definitions may be used. Regardless of the definition of the passband, the transitions between the passbands and the adjacent frequency bands (which have substantially higher insertion loss) are commonly called the upper edge (e.g., “fU”) and lower edge (e.g., “fL”) of the passband. An edge of a passband is commonly referred to as “sharp” if the transition from low loss to high rejection over a small frequency span.

Moreover, S-parameters are a convention used to describe the performance of linear electrical networks. As shown in graph 800, the solid line 810 is a plot of S(2,1), which is the voltage transfer function from port 1 (e.g., the “IN” port) to port 2 (e.g., the “OUT” port) of an electrical network. S(2,1) is often expressed in dB, which is 20 log 10 [S(2,1)] and is essentially the power gain of the device. However, passive devices like SAW filters are usually characterized by the “insertion loss” of the filter, which is numerically the same as the power gain, but with a change in numeric sign (e.g., S(2,1)=−3 dB is equivalent to an insertion loss of 3 dB). In this case, the solid line 810 plots the input-to-output transfer function of the filter 600. For convenience, these S-parameters are assumed to be expressed in dB. In this example, the passband is 2.30 to 2.41 GHz when defined as the frequency band where S(2, 1) is greater than-3 dB (less than 3 dB insertion loss).

Also shown in the graph 800A are the frequency locations of transmission zeros created by either the motional resonance of shunt connected devices, or the anti-resonance of series connected devices. The transmission zero frequency locations as indicated by dashed and broken arrows extending downward from the top of the graph. These arrows are shown for convenience in understanding the shape of the insertion loss response and are not part of the measured or simulated response of the bandpass filter 600. Three dashed arrows 820 represent transmission zeros caused by the motional resonances of shunt resonators 620B, 620C and 620D. Five broken (dash-dot-dot) arrows 840 represent transmission zeros caused by the anti-resonances of series resonators 610A to 610E.

Two broken (dash-dot) arrows 830 represent transmission zeros caused by the motional resonances of extracted pole shunt resonators 620A and 620E. By setting the motional resonant frequencies of the two extracted pole shunt resonators to frequencies (e.g., 2420 MHz and 2423 MHz) just above the upper edge fU of the passband, two high-Q transmission zeros create a very sharp upper passband edge. The transmission zero at 2420 MHz may be described as “adjacent to” the upper edge of the passband since it is closer to the upper edge than any other transmission zero.

Transmission zeros created by shunt resonators typically have higher Q than transmission zeros created by series resonators. Due to the generally higher Q of the resonance of the extracted-pole shunt resonators 620A and 620E that create the transmission zeros 830 just above the upper edge fU of the passband, these resonators degrade the insertion loss at the upper portion of the passband less than transmission zeros created by the anti-resonance of series resonators at similar frequencies. Additionally, since transmission zeros 830 just above the upper edge of the passband are created by extracted-pole shunt resonators 620A and 620E, the transmission zeros 840 due to the anti-resonance of series resonators 610A to 610E are located at higher frequencies, away from the passband, which also reduces insertion loss in the higher frequency portion of the passband.

Referring back to FIG. 6, the resonant frequency of the extracted pole resonators 620A and 620E of filter 600 can be configured (e.g., set or defined) according to different techniques. As described above, in a first exemplary aspect, the thickness (or stack) of the high side extracted pole resonator can be minimized to increase the resonator frequency. Conversely, the thickness (or stack) of the low side extracted pole resonators can be increased to reduce the resonator frequency. In some cases, a high side extracted pole resonator may have a dielectric thickness that would be less than that of dielectric thicknesses for any of series resonators, or less than an average dielectric thickness of series resonators. For a low side extracted pole resonator, dielectric thickness may be less than the dielectric thickness of any of the shunt resonators, or less than average dielectric thickness of series resonators. For example, as described above with respect to FIGS. 2A, 2B, 2C and 2D, a dielectric layer (e.g., a first dielectric coating layer or material) can be formed on one or both surfaces of the piezoelectric layer 110. In order to adjust the resonance frequency of a particular XBAR device, such as the extracted pole resonators 620A and 620E, a dielectric layer on either the first and/or second surfaces of the piezoelectric layer can be trimmed (e.g., etched) to adjust the resonance frequency. In this exemplary aspect, the dielectric layer(s) of the extracted pole resonators 620A and 620E can be trimmed to reduce an overall thickness (i.e., in the vertical or stack direction), such that the thickness is less than a thickness of the series resonators 610A to 610E of the filter 600. Alternatively, the thickness of the dielectric layer(s) can be increased to increase the resonant frequency. Effectively, the high side extracted pole resonator (one of resonators 620A and 620E) is configured to have a resonant frequency that is greater that a frequency of the upper edge fU of the passband filter 600 and also an antiresonance that is less an antiresonance fa of series resonators 610A to 610E. Moreover, the low side extracted pole resonator (the other of resonators 620A and 620E) is configured to have a resonant frequency that is less that a frequency of the low edge fL of the passband filter 600 and also an antiresonance that is greater an antiresonance fa of shunt resonators 620B, 620C, and 620D.

Thus, according to this configuration, the one or more dielectric layers that are disposed over the surface of the respective diaphragms of the plurality of series acoustic resonators 610A to 610E is thicker than the one or more dielectric layers that is disposed over the surface of the respective diaphragm of the high side extracted pole resonator. Moreover, the one or more dielectric layers are thinner than the one or more dielectric layers that are disposed over the surface of the respective diaphragms of the plurality of shunt acoustic resonators 620B, 620C and 620D other than the high side extracted pole resonator. Yet further, the one or more dielectric layers that are disposed over the surface of the respective diaphragms of the plurality of shunt acoustic resonators 620B, 620C and 620D are less than the one or more dielectric layers that are disposed over the surface of the respective diaphragm of the low side extracted pole resonator. It is noted again that the respective thicknesses are measured in a direction orthogonal to respective surfaces of the diaphragms.

In an example, the filter 600 can be formed of a single piezoelectric layer, which can be a piezoelectric plate or layer in one exemplary aspect, which spans a plurality of cavities as described above. In an exemplary aspect, the thickness ts of the piezoelectric layer (e.g., piezoelectric layer 110) can be approximately 330 nm. Moreover, a dielectric layer can be disposed over one or both surfaces of the piezoelectric layer, for example, to cover the IDT conductive pattern and/or on an opposite side thereof. During manufacture, the dielectric layer can be patterned and trimmed (e.g., by etching) to set the thickness for each XBAR of filter 600. For example, the dielectric layer over the conductive pattern of each of the series resonators (e.g., series resonators 610A to 610E) can be trimmed to approximately 50 nm. Moreover, the dielectric layer over the conductive pattern of each of the shunt resonators (e.g., shunt resonators 620B, 620C, and 620D) can be trimmed to approximately 120 nm. The high side extracted pole resonator (e.g., one of resonators 620A and 620E) can be a shunt resonator, with a dielectric layer that is trimmed to be less than that of the series resonators. The low side extracted pole resonator (e.g., the other of resonators 620A and 620E) can be a shunt resonator, with a dielectric layer that is thicker than that of the shunt resonators. For example, the dielectric layer of the high side extracted pole resonator can be trimmed to be 30 nm, for example, whereas the low side extracted pole resonator can be thicker than 120 nm. Effectively, the extracted pole resonators are shunt resonators in an XBAR configuration, but with a stack thickness either thinner than the series resonators of the filter 600 or a stack thickness thicker than the shunt resonators of the filter 600.

As also noted above, while the exemplary aspect contemplates trimming the dielectric layers over each acoustic resonator to set the resonant frequency, in an alternative aspect, the respective resonant frequencies can be set by varying the thickness of the respective diaphragms. In this aspect, respective diaphragms of the plurality of series acoustic resonators 610A to 610E can have a thickness that is greater than a thickness of respective diaphragms of the high side extracted pole resonators (one of resonators 620A and 620E). Moreover, respective diaphragms of the plurality of shunt acoustic resonators 620B, 620C, and 620D other than the high side extracted pole resonator can have a thickness that is greater than the thickness of respective diaphragms of the plurality of series acoustic resonators 610A to 610E. The low side extracted pole resonator (the other of resonators 620A and 620E) can have a diaphragm with a thickness greater than that of the plurality of shunt acoustic resonators 620B, 620C, and 620D. Again, the resonant frequency of each acoustic resonator is directly dependent on the stack thickness (thickness dependent on the thickness of the diaphragm and/or thickness of the dielectric layer(s)), with thinner stacks having a higher resonant frequency. Thus, varying the thicknesses of the diaphragm alone, or in combination with the dielectric layer) also can achieve the extracted pole techniques described herein.

According to various exemplary aspects, the extracted pole resonators (e.g., resonators 620A and 620E) can be formed in a different stack from the other resonators in the filter 600. As also described above, if the filter 600 is formed of a single-die, such that all resonators 610A to 610E and 620A to 620E, have the same piezoelectric film thickness, the series resonators 610A to 610E will have a dielectric coating thickness t1, whereas the shunt resonators 620B, 620C and 620D will have a dielectric coating t2 where thickness t2 is greater than thickness t1, such that the shunt resonators 620B, 620C and 620D have a lower resonance frequency than the series resonators 610A to 610E. Moreover, in the exemplary aspect, the high side extracted pole resonator (one of 620A and 620E) will have coating thickness to that is less than thickness t1 to move its respective frequency higher than the series resonators 610A to 610E as described above. The low side extracted pole resonator (the other of 620A and 620E) will have coating thickness t3 that is greater than thickness t2 to move its respective frequency lower than the shunt resonators 620B, 620C and 620D, as described above. Similarly if other techniques are used, such as multiple die or piezoelectric layer (diaphragm) trimming, the high side extracted pole resonator may be constructed on a stack to have a higher frequency than the series resonators 610A to 610E and the low side extracted pole resonator may be constructed on a stack to have a lower frequency than the shunt resonators 620B to 620D.

In an alternative aspect, the pitch p of extracted pole resonators 620A and 620E can be adjusted to set the resonance frequencies in filter 600. For example, shunt resonators in a ladder filter circuit typically have a lower resonance frequency than the series resonators. However, in this aspect, the high side extracted pole resonator (one of resonators 620A and 620E) can have a pitch of its respective IDT fingers that is smaller than respective pitches of the series resonators 610A to 610E of the filter 600. Moreover, in this aspect, the low side extracted pole resonator (the other one of resonators 620A and 620E) can have a pitch of its respective IDT fingers that is larger than respective pitches of the shunt resonators 620B,620C and 620D 610A to 610E of the filter 600. This configuration also sets the high side extracted pole resonator to have a resonant frequency that is greater than a frequency of the upper edge fU of the passband filter 600 and also an antiresonance that is less an antiresonance fa of series resonators 610A to 610E. In addition, this configuration sets the low side extracted pole resonator to have a resonant frequency that is lower than a frequency of the lower edge fL of the passband filter 600 and also an antiresonance that is greater an antiresonance fa of shunt resonators 620B to 620D. Thus, varying the pitches can be used to set the resonance frequencies of the individual XBARs (i.e., resonators 620A and 620E) and thus adjust the frequency characteristics of filter device 600 as a whole in operation. This configuration also avoids the need to vary the thicknesses of the different XBARs of the filter, which in turn will reduce manufacturing steps and also reduce the overall size of the device.

Thus, an exemplary aspect, if a series resonator (e.g., resonator 610A) has a ratio of a pitch to diaphragm thickness of approximately ˜6-11, for example, the high side extracted pole resonator, either 620A or 620E, may have a ratio of a pitch to diaphragm thickness of approximately ˜3-4. As described, the small pitch resonator will have both higher frequency and reduced coupling, which allows it to satisfy the conditions for the extracted pole technique.

In sum, the resonance frequency and antiresonance of the extracted pole resonators 620A and 620E according to various exemplary aspects can be configured by setting the overall thickness of the resonator stack (e.g., by dielectric trimming or diaphragm trimming) or by reducing and increasing the pitch of the IDT fingers. In general, it should be appreciated that both techniques may also be used together such that the extracted pole resonators 620A and 620E are both on a distinct stack from series and shunt resonators, and also utilize ad adjusted pitch to diminish the coupling and control the frequency.

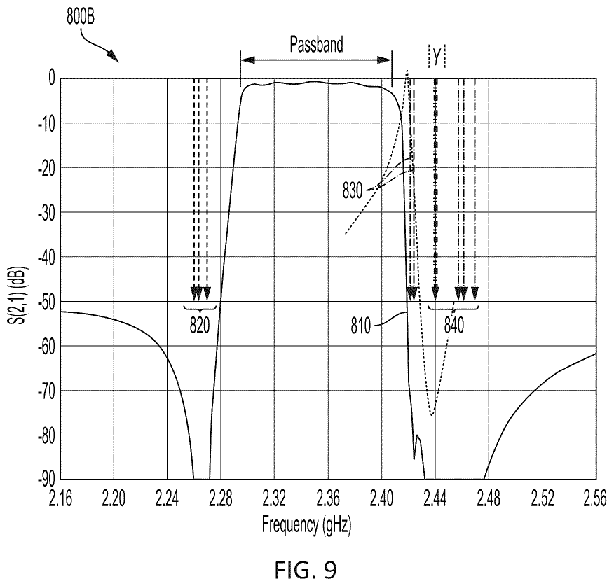

FIG. 9 illustrates a graph 800B that demonstrates a predictive response of extracted pole resonator 620A (i.e., shunt resonator X2) on S(2,1) parameter of the bandpass filter 600 shown in graph 800A described above. The plot is also obtained using a FEM simulation technique. As shown, the response Y of extracted pole resonator 620A is shown as superimposed on the passband to demonstrate the increased steepness of the upper edge fU of the passband. Advantageously, using the extracted pole technique described above, enhances the rejection of resonances outside the passband with increased band edge steepness. Moreover, the extracted pole resonators improve a one-sided rejection to create a deeper stopband (i.e., as shown in the upper edge fU of the passband) than a standard ladder filter.

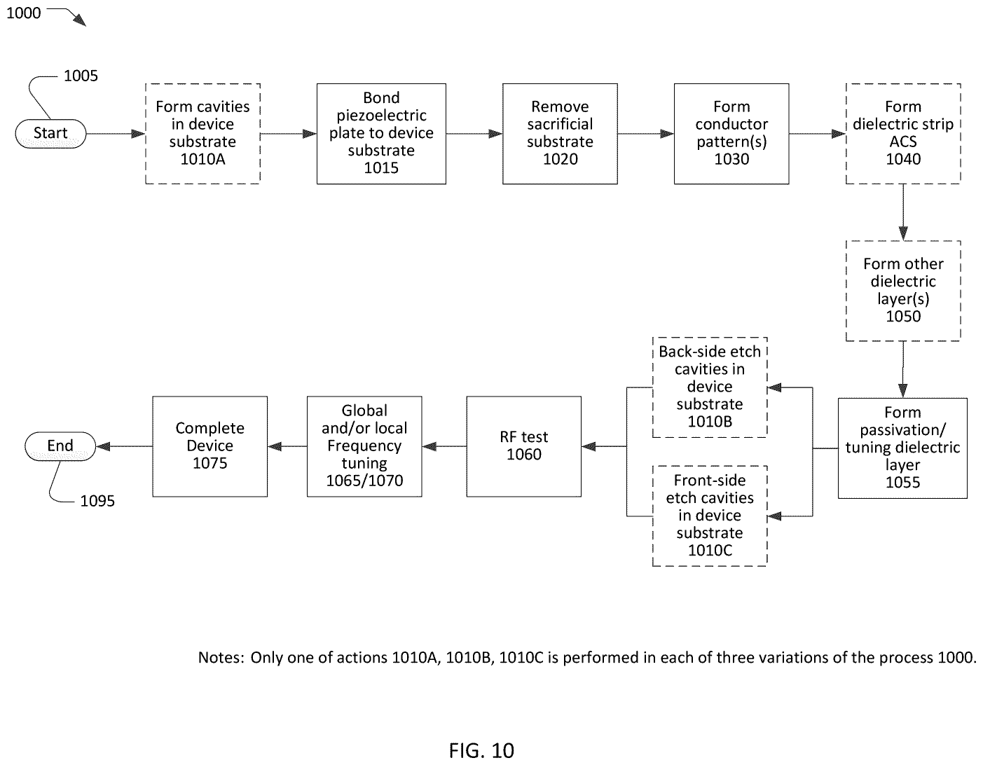

FIG. 10 illustrates a flowchart of a method of manufacturing a filter as described herein according to an exemplary aspect. In particular, method 1000 summarizes an exemplary manufacturing processing for fabricating a filter device incorporating XBARs as described herein. Specifically, the process 1000 is for fabricating a filter device including multiple XBARs, including extracted pole resonators. The process 1000 starts at 1005 with a device substrate and a thin layer of piezoelectric material disposed on a sacrificial substrate. The process 1000 ends at 1095 with a completed filter device. It is noted that the flow chart of FIG. 10 includes only major process steps. Various conventional process steps (e.g., surface preparation, cleaning, inspection, baking, annealing, monitoring, testing, etc.) may be performed before, between, after, and during the steps shown in FIG. 10.

While FIG. 10 generally describes a process for fabricating a single filter device, multiple filter devices may be fabricated simultaneously on a common wafer (including a piezoelectric layer bonded to a substrate). In this case, each step of the process 1000 may be performed concurrently on all of the filter devices on the wafer.

The flow chart of FIG. 10 captures three variations of the process 1000 for making an XBAR which differ in when and how cavities are formed in the device substrate. The cavities may be formed at steps 1010A, 1010B, or 1010C. Only one of these steps is performed in each of the three variations of the process 1000.

In an exemplary aspect, the piezoelectric layer may typically be Z-cut or 82Y-cut lithium niobate. The piezoelectric layer may be some other material and/or some other cut. The device substrate may preferably be silicon. The device substrate may be some other material that allows formation of deep cavities by etching or other processing.

In one variation of the process 1000, one or more cavities are formed in the device substrate at 1010A, before the at least one piezoelectric layer is bonded to the substrate at 1015. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities may be formed using conventional photolithographic and etching techniques. Typically, the cavities formed at 1010A will not penetrate through the device substrate.

At 1015, the at least one piezoelectric layer is bonded to the device substrate. The at least one piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. One or both mating surfaces may be activated using, for example, a plasma process. The mating surfaces may then be pressed together with considerable force to establish molecular bonds between the piezoelectric layer and the device substrate or intermediate material layers.

At 1020, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 1020, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

A first conductor pattern, including IDTs of each XBAR, is formed at 1030 by depositing and patterning one or more conductor layers on the front side of the piezoelectric layer. The conductor layer may be, for example, aluminum, an aluminum alloy, copper, a copper alloy, or some other conductive metal. In some aspects, one or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Each conductor pattern may be formed at 1030 by depositing the conductor layer and, in some aspects, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 1030 using a lift-off process. Photoresist may be deposited over the piezoelectric layer and patterned to define the conductor pattern. The conductor layer and, in some aspects, one or more other layers may be deposited in sequence over the surface of the piezoelectric layer. The photoresist may then be removed, which removes the excess material, leaving the conductor pattern.

As described above, the resonant frequencies of each acoustic resonator may be set according to the configured pitch of each IDT in one aspect. Thus, at 1030, the pitch of the high side extracted pole resonator may be set to be smaller than the pitches of series resonators 610A to 610E, for example, such that they have a higher frequency. Moreover, the pitch of the low side extracted pole resonator may be set to be larger than the pitches of shunt resonators 620B to 620D, for example, such that they have a lower frequency.

In an optional aspect, at 1040, one or more dielectric strips may be formed. In particular, dielectric strips may overlap the ends of the IDT fingers in the margins of the aperture and extend into the gaps between the ends of the IDT fingers and adjacent busbars. The dielectric strips may be formed by depositing and patterning, using either etching or a lift-off technique, a dielectric thin film. The dielectric strips may be silicon dioxide, silicon nitride, aluminum oxide, or some other dielectric material. The dielectric strips may be multiple layers of different materials or a mixture of two or more materials.

As also described above, the stack thicknesses of each acoustic resonator can be adjusted to vary the resonant frequency of the respective device of the filter 600. Accordingly, at 1050, one or more frequency setting dielectric layer(s) may be formed in some aspects by depositing one or more layers of dielectric material on the front side of the piezoelectric layer. For example, a thicker dielectric layer may be provided over shunt resonators to lower the frequencies of the shunt resonators relative to the frequencies of series resonators. Moreover, a thinner dielectric layer may be provided over the high side extracted pole resonator and a thicker dielectric layer may be provided over the low side extracted pole resonator. In an exemplary aspect, the one or more dielectric layers may be deposited using a conventional deposition technique such as physical vapor deposition, atomic layer deposition, chemical vapor deposition, or some other method. One or more lithography processes (using photomasks) may be used to limit the deposition of the dielectric layers to selected areas of the piezoelectric layer. For example, a mask may be used to limit a dielectric layer to cover only the shunt resonators.

At 1055, a passivation/tuning dielectric layer may be deposited over the piezoelectric layer and conductor patterns. The passivation/tuning dielectric layer may cover the entire surface of the filter except for pads for electrical connections to circuitry external to the filter. In some instantiations of the process 1000, the passivation/tuning dielectric layer may be formed after the cavities in the device substrate are etched at either 1010B or 1010C.

In a second variation of the process 1000, one or more cavities are formed in the back side of the device substrate at 1010B. A separate cavity may be formed for each resonator in a filter device. Also, the cavities can be shaped and formed such that plurality of resonators can be on one diaphragm over one cavity. These resonators sharing a diaphragm are acoustically coupled on an acoustic track. The one or more cavities may be formed using an anisotropic or orientation-dependent dry or wet etch to open holes through the back side of the device substrate to the piezoelectric layer. In this case, the resulting resonator devices will have a cross-section as shown in FIG. 1A.

In a third variation of the process 1000, one or more cavities in the form of recesses in the device substrate may be formed at 1010C by etching the substrate using an etchant introduced through openings in the piezoelectric layer. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities formed at 1010C will not penetrate through the device substrate.

Ideally, after the cavities are formed at 1010B or 1010C, most or all of the filter devices on a wafer will meet a set of performance requirements. However, normal process tolerances will result in variations in parameters such as the thicknesses of dielectric layers formed at 1050 and 1055, variations in the thickness and line widths of conductors and IDT fingers formed at 1030, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 1055. The frequency of a filter device passband can be lowered by adding material to the passivation/tuning layer, and the frequency of the filter device passband can be increased by removing material from the passivation/tuning layer. Typically, the process 1000 is biased to produce filter devices with passbands that are initially lower than a required frequency range but can be tuned to the desired frequency range by removing material from the surface of the passivation/tuning layer.

At 1060, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 1065, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 1060 may be processed to generate a global contour map indicating the amount of material to be removed as a function of two-dimensional position on the wafer. The material is then removed in accordance with the contour map using the selective material removal tool.

At 1070, local frequency tuning may be performed in addition to, or instead of, the global frequency tuning performed at 1065. “Local” frequency tuning is performed with a spatial resolution smaller than an individual filter device. The test results from 1060 may be processed to generate a map indicating the amount of material to be removed at each filter device. Local frequency tuning may require the use of a mask to restrict the size of the areas from which material is removed. For example, a first mask may be used to restrict tuning to only shunt resonators, a second mask may be subsequently used to restrict tuning to only series resonators, and a third mask may be subsequently used to restrict tuning to only extracted pole resonators. This would allow independent tuning of the lower band edge and upper band edge of the filter devices.

After frequency tuning at 1065 and/or 1070, the filter device is completed at 1075. Actions that may occur at 1075 include forming bonding pads or solder bumps or other means for making connection between the device and external circuitry (if such pads were not formed at 1030); excising individual filter devices from a wafer containing multiple filter devices; other packaging steps; and additional testing. After each filter device is completed, the process ends at 1095.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bandpass filter comprising:
a plurality of bulk acoustic resonators each comprising:
a piezoelectric layer,
an interdigital transducer (IDT) on the piezoelectric layer and having a plurality of interleaved fingers, and
a dielectric layer disposed on and between the interleaved fingers of the IDT,
wherein the plurality of bulk acoustic resonators includes:
a plurality of series resonators connected in series between an input and an output of the bandpass filter,
a plurality of shunt resonators that are each connected between a ground and a node between a respective pair of the plurality of series resonators,
a first extracted pole resonator connected between the ground and a node between the input and a first series resonator from among the plurality of series resonators, and
a second extracted pole resonator connected between the ground and a node between the output and a last series resonator from among the plurality of series resonators, and
wherein one of the first and second extracted pole resonators has a resonance frequency that is higher than an upper edge of a passband of the bandpass filter.

2. The bandpass filter according to claim 1, wherein the other of the first and second extracted pole resonators has a resonance frequency that is lower than a lower edge of the passband of the bandpass filter.

3. The bandpass filter according to claim 1, wherein each of the plurality of bulk acoustic resonators comprises a substrate and an intermediate dielectric layer that couples the substrate to the piezoelectric layer, and wherein the piezoelectric layer includes a diaphragm over a cavity in the intermediate dielectric layer with the interleaved fingers of the respective IDT on the diaphragm.

4. The bandpass filter according to claim 1, wherein a thickness of the respective dielectric layers of each of the first and second extracted pole resonators is different than a thickness of the respective dielectric layers of the plurality of series resonators and the plurality of shunt resonators.

5. The bandpass filter according to claim 4, wherein the thickness of the respective dielectric layers of the plurality of series resonators is thicker than the thickness of respective dielectric layer of the one of the first and second extracted pole resonators that has the resonance frequency that is higher than the upper edge of the passband of the bandpass filter.

6. The bandpass filter according to claim 5, wherein the thickness of the respective dielectric layers of the plurality of shunt resonators is thinner than the thickness of respective dielectric layer of the other of the first and second extracted pole resonators that has a resonance frequency that is lower than a lower edge of the passband of the bandpass filter.

7. The bandpass filter according to claim 6, wherein the respective thicknesses of the dielectric layers of the plurality of bulk acoustic resonators are measured in a direction orthogonal to surfaces of the respective piezoelectric layers.

8. The bandpass filter according to claim 1, wherein a thickness of the respective piezoelectric layers of each of the first and second extracted pole resonators is different than a thickness of the respective piezoelectric layers of the plurality of series resonators and the plurality of shunt resonators.

9. The bandpass filter according to claim 1, wherein a stack thickness of each of the first and second extracted pole resonators is different than a stack thickness of the plurality of series resonators and the plurality of shunt resonators.

10. The bandpass filter according to claim 9, wherein the stack thickness of the plurality of series resonators is thicker than the stack thickness of the one of the first and second extracted pole resonators that has the resonance frequency that is higher than the upper edge of the passband of the bandpass filter.

11. The bandpass filter according to claim 10, wherein the stack thickness of the plurality of shunt resonators is thinner than the stack thickness of the other of the first and second extracted pole resonators that has a resonance frequency that is lower than a lower edge of the passband of the bandpass filter.

12. The bandpass filter according to claim 11, wherein the respective stack thicknesses of the plurality of bulk acoustic resonators are measured in a direction orthogonal to surfaces of the respective piezoelectric layers.

13. The bandpass filter according to claim 1, wherein a pitch of the respective IDTs of each of the first and second extracted pole resonators is different than a pitch of the respective IDTs of the plurality of series resonators and the plurality of shunt resonators.

14. The bandpass filter according to claim 13, wherein the pitch of the respective IDTs of the plurality of series resonators is larger than a pitch of the one extracted pole resonator that has the resonance frequency that is higher than the upper edge of the passband of the bandpass filter.

15. The bandpass filter according to claim 14, wherein the pitch of the respective IDTs of the plurality of shunt resonators is less than a pitch of the other of the first and second extracted pole resonators has a resonance frequency that is lower than a lower edge of the passband of the bandpass filter.

16. The bandpass filter according to claim 1, wherein the respective IDTs of each of the plurality of bulk acoustic resonators are configured to excite primary shear acoustic waves in the respective piezoelectric layer in response to a radio frequency signal or a microwave signal applied to the IDT.

17. The bandpass filter according to claim 1, wherein each of the plurality of bulk acoustic resonators comprises a substrate and a Bragg reflector that couples the substrate to the piezoelectric layer.

18. A bandpass filter comprising:
a plurality of bulk acoustic resonators each comprising:
a piezoelectric layer,
an interdigital transducer (IDT) on the piezoelectric layer and having a plurality of interleaved fingers, and
a dielectric layer disposed on and between the interleaved fingers of the IDT,
wherein the plurality of bulks acoustic resonators includes:
a plurality of series resonators connected in series between an input and an output,
a plurality of shunt resonators that are each connected between a ground and a node that is between a respective pair of series resonators of the plurality of series acoustic resonators,
a high side extracted pole resonator connected between the ground and either the input or the output, and
a low side extracted pole resonator connected between the ground and the other of the input or the output, and
wherein the high side extracted pole resonator has a resonance frequency that is higher than an upper edge of a passband of the bandpass filter and the low side extracted pole resonator has a resonance frequency that is lower than a lower edge of a passband of the bandpass filter.

19. The bandpass filter according to claim 18, wherein:
a stack thickness of the plurality of series resonators is thicker than a stack thickness of the high side extracted pole resonator,
a stack thickness of the plurality of shunt resonators is thinner than a stack thickness of the low side extracted pole resonator, and
the respective stack thicknesses of the plurality of bulk acoustic resonators are measured in a direction orthogonal to surfaces of the respective piezoelectric layers.

20. The bandpass filter according to claim 18, wherein the respective IDTs of each of the plurality of bulk acoustic resonators are configured to excite primary shear acoustic waves in the respective piezoelectric layer in response to a radio frequency signal or a microwave signal applied to the IDT.
